(19) United States
(12) Patent Application Publication
(10) Pub. No.: US 2008/0173999 A1
(43) Pub. Date: Jul. 24, 2008

(54) STACK PACKAGE AND METHOD OF MANUFACTURING THE SAME

(75) Inventors: Hyun-Soo CHUNG, Gyeonggi-do (KR); Dong-Hyeon JANG, Gyeonggi-do (KR); Tae-Gyeong CHUNG, Gyeonggi-do (KR); Nam-Seog KIM, Gyeonggi-do (KR); Seung-Kwan RYU, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/969,037

(22) Filed: Jan. 3, 2008

(30) Foreign Application Priority Data
Jan. 23, 2007 (KR) 2007-0007253

(51) Int. Cl. H01L 23/538

(52) U.S. Cl. 257/686; 257/E23.169

(57) ABSTRACT

A stack package and a method of manufacturing the same are provided. The stack package includes one or more interposers in which a semiconductor chip having a bonding pad are inserted, an interconnection terminal groove is formed due to a difference of the areas between the semiconductor chip and a cavity into which the semiconductor chip is inserted, and an interconnection terminal connected to the bonding pad is formed in the interconnection terminal groove. In the stack package, the interposers are stacked with one another and the interconnection terminals are connected to one another such that one or more semiconductor chips are stacked and electrically connected.

### CROSS-REFERENCE TO RELATED PATENT APPLICATION

This application claims priority under 35 USC § 119 to Korean Patent Application No. 10-2007-0007253, filed on Jan. 23, 2007 in the Korean Intellectual Property Office, the contents of which are incorporated herein in their entirety by reference.

### BACKGROUND

1. Technical Field

The present invention relates to a stack package and a method for manufacturing the same, and more particularly, to a stack package capable of improving an electrical connection property between semiconductor chips stacked with each other and enhancing the yield of packaging, and a method of manufacturing the stack package.

2. Description of the Related Art

In the last several years, consumer demand has moved increasingly toward small, light, high-speed and high-capacity electronic products. In order to meet the demand for small electronic products, semiconductor chip packages have become smaller and lighter. In order to satisfy such requirements, research has been increasingly directed to packaging technologies such as a flip chip, in which an existing wire bonding method is not applied, a wafer level package, which is packaged in the state such that a semiconductor chip is not separated from a wafer, and the like.

In particular, a stack package has been developed with a structure in which metallic through electrodes are formed using through via holes formed in semiconductor chips and these metallic through electrodes are then connected to one another such that the semiconductor chips are connected directly to one another. In this case, since bonding wires are not used, the stack package can have a small form-factor. Further, since the length of the metallic through electrode is shorter than that of the bonding wire, high-performance, high-speed and low-power stack packages are possible.

FIG. 1 is a cross-sectional view showing a structure of a conventional stack package, and FIG. 2 is a plan view showing a wafer before dicing into individual semiconductor chips.

Referring to FIGS. 1 and 2, a metal pad 40 and a passivation layer (not shown) are first stacked on the semiconductor chip 90 and then patterned. Next, a redistribution pattern 35 electrically connecting the metal pad 40 to a metallic through electrode 30, positioned apart from the metal pad 40, is formed on the semiconductor chip 90.

A method of forming the redistribution pattern 35 is as follows: First, the position of a metallic through electrode 30 is set in a region defined by scribe lines 80 that are individual border lines or dicing lines of a semiconductor chip 90, and a through via hole 95 is formed at the position of the metallic through electrode 30 using laser drilling. A seed metal layer 34 is deposited in the through via hole 95 and then patterned into a predetermined shape through a photolithography process including exposure and development processes so as to form a redistribution pattern 35. That is, the redistribution pattern 35 is formed through the photolithography process, and portions other than the redistribution pattern 35 are removed through an etching process.

If the redistribution pattern 35 is formed by depositing the seed metal layer 34 in a predetermined region including the through via hole 95 and the metal pad 40 and then patterning the seed metal layer 34, the metallic through electrode 30 is formed by filling a metallic material in the through via hole 95 through a plating process. Next, a back lap process is performed to reduce the thickness of the semiconductor chip 90 and the metallic through electrodes 30 of the semiconductor chips 90 are then connected to one another using solder balls or bumps 20, so that the semiconductor chips 90 can be electrically connected to one another. The semiconductor chips 90 connected to one another are connected to electrodes of a substrate 10 using the solder balls or bumps 20.

However, according to the conventional method, since the position of the metallic through electrode 30 is defined by the scribe lines 80, there are limited options available to set the position of the metal pad 40 or the metallic through electrode 30. Further, cracks may be produced at the position of the redistribution pattern 35 or metallic through electrode 30 when dicing the semiconductor chip 90 along the scribe line 80. This causes several problems in that a yield may be lowered, a wafer or semiconductor chip 90 may be broken during drilling for forming the through via hole 95, a process for removing foreign matter associated with the formation of the through via hole 95 is required, current leakage due to the foreign matter may occur, and the entire process becomes more complicated. The present invention addresses these and other disadvantages of the conventional art.

### SUMMARY

The present invention provides a stack package capable of enhancing not only an electrical property of the stack package but also the reliability and the mass-production yield through a simple process, and a method of manufacturing the stack package.

According to an aspect of the present invention, there is provided a stack package which includes: semiconductor chips each having a bonding pad; interposers each having a cavity into which the semiconductor chip is inserted and an interconnection terminal groove between the semiconductor chip and a sidewall of the cavity; and a redistribution pattern connecting the bonding pad to interconnection terminals formed in the interconnection terminal groove, wherein the rear surface of the interposer is polished such that the interconnection terminals are exposed.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view showing a structure of a conventional stack package;

FIG. 2 is a plan view showing a wafer before dicing into individual semiconductor chips;

FIG. 3 is a cross-sectional view showing a structure of a stack package according to some embodiments of the present invention;

FIGS. 4 through 6 are cross-sectional views illustrating a method of manufacturing a stack package according to some embodiments of the present invention; and

FIG. 7 is a plan view of the stack package of FIG. 3.

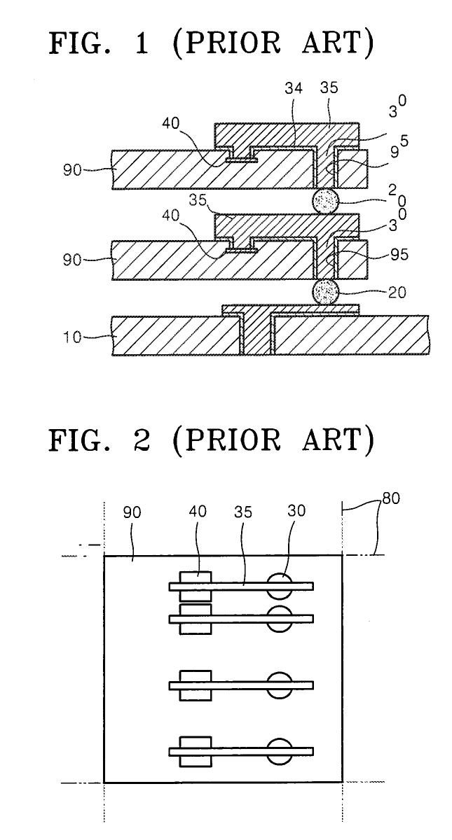

### DETAILED DESCRIPTION

The present invention will now be described more fully hereinafter with reference to the accompanying drawings, in which preferred embodiments of the invention are shown. This invention may, however, be embodied in many different forms and should not be construed as being limited to the embodiments set forth herein.

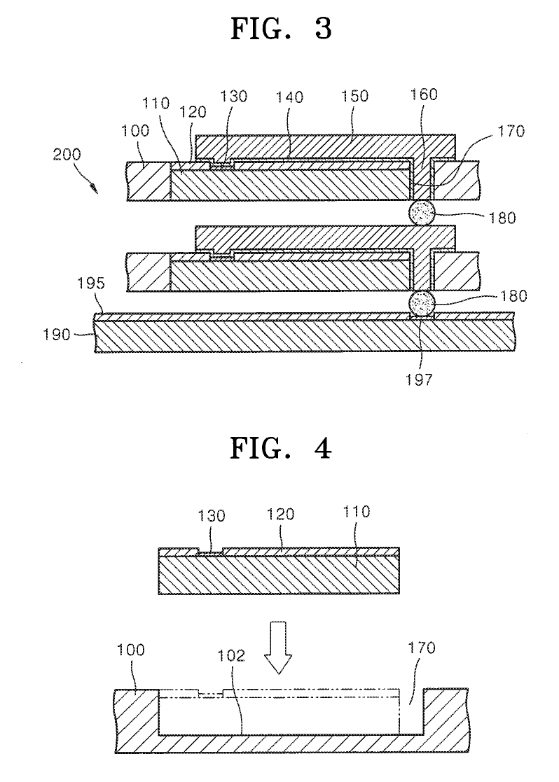

FIG. 3 is a cross-sectional view showing a structure of a stack package 200 according to some embodiments of the present invention. Referring to this figure, the stack package 200 includes semiconductor chips 110 and interposers 100. Each of the semiconductor chips 110 is inserted into a corresponding one of the interposers 100. In the stack package 200, the semiconductor chips 110 and interposers 100 are stacked by being vertically arranged. On each of the semiconductor chips 110 is formed a bonding pad 130, exposed so as to be connected to a wire (not shown) or redistribution pattern 150 for the purpose of supplying signals or power, and a passivation layer 120 for protecting a surface of the semiconductor chip 110. For example, the bonding pad 130 may be formed as an aluminum layer, and the passivation layer 120 may be formed as a silicon nitride layer (SiN).

The semiconductor chips 110 may be vertically stacked while each of the semiconductor chips 110 is inserted into the interposer 100. The interposer 100 includes a cavity 102 (shown in FIG. 4) having an area broader than the semiconductor chip 110, as a place into which the semiconductor chip 110 is inserted, and an interconnection terminal groove 170 that is a space produced in the cavity 102 due to a difference of the areas between the cavity 102 and the semiconductor chip 110. In other words, the interconnection terminal groove comprises a portion of the cavity 102 between the semiconductor chip 110 and a sidewall of the cavity 102. A portion of the interconnection terminal groove 170 is filled with a metallic material so as to form an interconnection terminal 160. The interconnection terminal 160 formed in the interposer 100 is connected to the bonding pad 130 through the redistribution pattern 150.

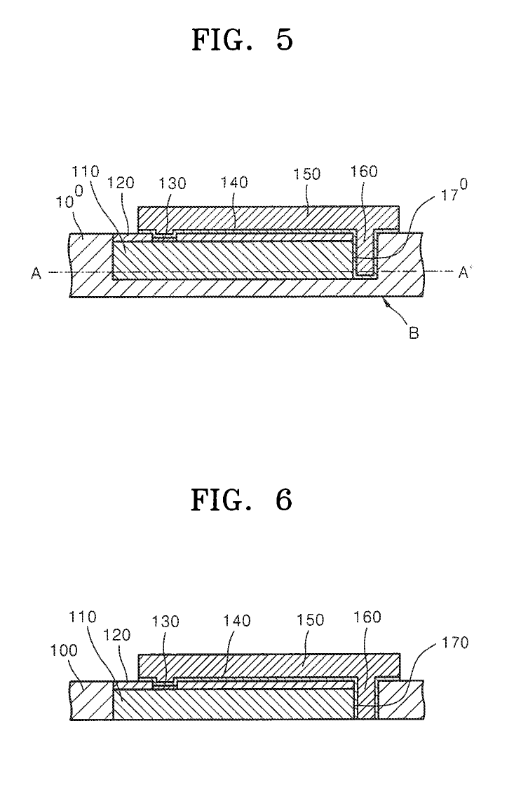

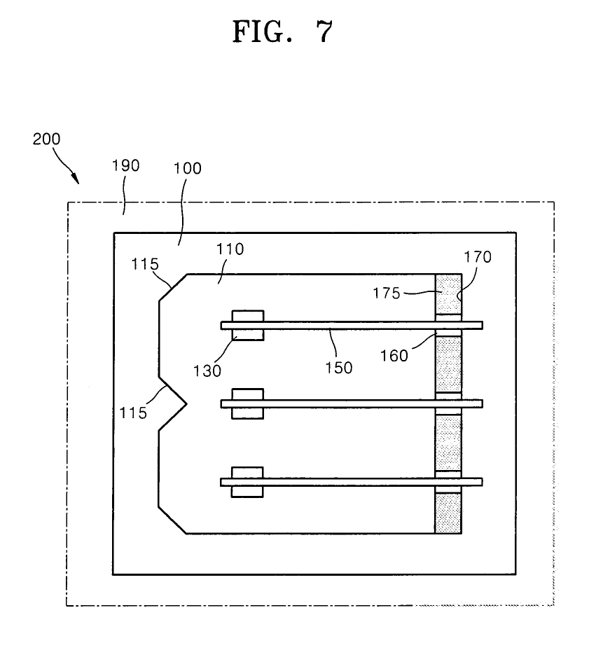

FIGS. 4 through 6 are cross-sectional views illustrating a method of manufacturing a stack package 200 according to some embodiments of the present invention. FIG. 7 is a plan view of the stack package 200 of FIG. 3. Hereinafter, a stack package 200 and a method of manufacturing the same will be described with reference to FIGS. 3 through 7.

Referring to FIG. 4, semiconductor chips 110 judged as good products by, for example, a testing process, (a semiconductor chip 110 may be referred to as a known good die (KGD)) are prepared. A plurality of interposers 100 are stacked, and interconnection terminals 160 each exposed by polishing the rear surface of the interposer 100 are connected to one another, so that the plurality of semiconductor chips 110 can be stacked with one another and electrically connected. The semiconductor chip 110, in the form of a single chip which is separated from a wafer through a dicing process, is illustrated in this figure. However, according to some embodiments of the present invention, the semiconductor chip 110 in a wafer state is inserted into the interposer 100, and the interconnection terminal 160 is formed in a gap between the interposer 100 and the wafer. Accordingly, a wafer-to-wafer stack structure, in which a plurality of interposers 100 each having an interconnection terminal 100 are stacked with one another, may be formed.

A silicon wafer, a glass substrate, or a printed circuit board (PCB) may be used as the interposer 100 of the present invention. In addition, any material capable of forming the interconnection terminal 160 and allowing the interconnection terminal 160 to be exposed by polishing the rear surface of the interposer 100 may be used as the interposer 100. Although the interposer 100 formed by dicing a wafer is illustrated in this figure, a silicon wafer itself that is not diced may be an embodiment of the present invention as well. That is, the interposers 100 of the present invention may be stacked in the condition that the interposers are formed by dicing a wafer or in the condition of a silicon wafer itself. When stacking interposers in the wafer state, a redistribution pattern is formed on the interposer in the wafer state and an interconnection terminal is exposed by polishing the rear surface of the interposer. Then, the interposers in the wafer state are stacked and then diced, or diced and then stacked.

A cavity 102 is formed in the interposer 100, and the semiconductor chip 110 is then inserted into the cavity 102. Although the depth of the cavity 102 is not limited, the area of the cavity 102 should be larger than that of the semiconductor chip 110. This is because an interconnection terminal groove 170 is provided in a space formed due to a difference of the areas between the cavity 102 and the semiconductor chip 110. Also, the fan out of the semiconductor chip 110 means that a region, in which interconnection elements such as pins or solder balls will be arranged, is extended using an additional member if the size of the semiconductor chip 110 is small to such a degree that it is difficult to arrange a large number of pins or solder balls. In the present invention, the fan out of the semiconductor chip 110 can be implemented by the interposer 100. To this end, the area of the interposer 100 is broader by an area required in implementing the fan out of the semiconductor chip 110 than that of the semiconductor chip 110.

Referring to FIG. 5, the interconnection terminal 160 is formed by plating a metal in the interconnection terminal groove 170. According to some embodiments, a redistribution pattern 150 connecting the interconnection terminal 160 to a bonding pad 130 may be formed by patterning a seed metal layer 140 on a surface of the semiconductor chip 110 and the interconnection terminal groove 170 and plating a metal on the seed metal layer 140. For example, a Ti/Cu layer is deposited on a passivation layer 120 or interconnection terminal groove 170 through a sputtering process and the seed metal layer is then patterned in a desired form through a photolithography process including exposure and etching processes. According to other embodiments, the redistribution pattern 150 may be patterned directly on the passivation layer and the interconnection terminal groove 170 without forming the seed metal layer 140. Any method of patterning using a photolithography process, plating or the like may be used to directly form the redistribution pattern 150.

If the rear surface B of the interposer 100 is polished up to line A-A′, the interconnection terminal 160 is exposed. When the plurality of interposers 100 are stacked with one another, a an external connection terminal 180 connects the exposed interconnection terminals 160 to each other or connects the interconnection terminal 160 to a substrate pad 197. The external connection terminal 180 may be a solder ball or metal bump made of Cu, Au, Ni or the like. A module substrate 190 includes a photo solder resist layer 195 and a substrate pad 197. The photo solder resist layer 195, which is an insulating passivation layer, is formed such that the substrate pad 197 formed on the module substrate 190 is exposed. The substrate pad 197 is connected to a wiring of the module substrate 190 such that signals and power are transmitted to the substrate pad 197.

In the stack package 200, a semiconductor chip 110 is inserted into an interposer 100 having a cavity 102, and a metal is filled in an interconnection terminal groove 170 formed due to a difference of the areas between the cavity 102 and the semiconductor chip 110, thereby forming an interconnection terminal 160. Next, the interconnection terminal 160 is exposed by polishing the rear surface of the interposer 100, the interposers 100 are stacked with one another, and electrical connection is then performed with respect to the interconnection terminals 160. Such a structure is much simpler than the conventional structure in which a through via hole is formed by laser drilling and a metallic through electrode is then formed in the through via hole. In the structure according to embodiments of the present invention, the occurrence of foreign matter or cracks due to laser drilling can be significantly reduced, the yield of a wafer stack package can be enhanced, and the breakdown of a wafer can be prevented. Further, since various embodiments such as wafer-to-wafer and single chip-to-single chip stacks can be implemented, the structure has excellent process applicability. Also, since the semiconductor chip 110 may be embedded in the interposer 100 using the stack structure of the present invention, the reliability of the structure is much superior to that of the conventional stack structure in which a through via hole is formed. The interconnection lengths of the interconnection terminal 160 and external connection terminal 180 become shorter, the interconnection densities thereof are enhanced, and an electrical property of the stack package 200 is significantly improved. Accordingly, high-speed, high-capacity and multifunctional packages can be implemented.

Referring to FIG. 7, an elastomer 175 is filled in a portion of the interconnection terminal groove 170. The elastomer 175 refers to a polymer that is extended if it is pulled using an external force and restored to the original length if the external force is removed. Alternatively, a polymer material having significant plasticity is referred to as a plastomer. Representative examples of the elastomer 175 are elastic rubber such as butadiene or styrene, and elastic fiber such as spandex. The elastomer 175 is used to protect the interconnection terminal 160 from an external force and to secure the interconnection stability of the interconnection terminal 160.

Moreover, an aligner 115 may be provided at the cavity 102. The aligner 115 is used to align the position of the semiconductor chip 110 when inserting the semiconductor chip 110 into the cavity 102. The aligner 115 is not limited in shape as shown in this figure but may have various other shapes and/or irregular shapes.

The method of manufacturing a stack package according to some embodiments of the present invention will be briefly described as follows: First, a semiconductor chip 110 is inserted into an interposer 100 having a cavity 102. A redistribution pattern 150 connecting an interconnection terminal 160 to a bonding pad 130 is formed, and the interconnection terminal 160 is formed in an interconnection terminal groove 170. The interconnection terminal 160 is exposed by polishing the rear surface of the interposer 100. An elastomer 175 may be filled in a portion of the interconnection terminal groove 170 as desired. Then, at least one or more interposers 100 are stacked with one another, and the interconnection terminals 160 are connected to one another. When assembling the stacked interposers 100 on a module substrate 190, the interconnection terminals 160 are connected to a substrate pad 197, thereby completing the stack package.

As described above, in a stack package and a method of manufacturing the same, according to some embodiments of the present invention, the occurrence of foreign matter or cracks due to laser drilling can be significantly reduced, the yield of a wafer stack package can be enhanced, and the breakdown of a wafer can be prevented. Further, since various embodiments such as wafer-to-wafer and single chip-to-single chip stacks can be implemented, the structure has excellent process applicability. Also, since a semiconductor chip may be embedded in an interposer using the stack structure of the present invention, the reliability of the structure is much superior to that of the conventional stack structure in which a through via hole is formed. Since the interconnection length and density of an interconnection terminal and an external connection terminal are improved and an electrical property of the stack package is significantly improved, high-speed, high-capacity and multifunctional packages can be implemented.

According to an aspect of the present invention, there is provided a stack package which includes: a plurality of semiconductor chips each having a bonding pad; a plurality of interposers each having a cavity in which the semiconductor chip is disposed and an interconnection terminal groove disposed between the semiconductor chip and a sidewall of the cavity; and a redistribution pattern connecting the bonding pad to interconnection terminals disposed in the interconnection terminal groove, wherein the interconnection terminals are exposed by a rear surface of the interposer.

Here, the plurality of interposers may be stacked with one another and the exposed interconnection terminals may be connected to one another such that the plurality of semiconductor chips are stacked with one another and electrically connected. The stack package may further include an elastomer filled in a portion of the interconnection terminal groove. The interposer may be one of a silicon wafer, a glass substrate, and a printed circuit board (PCB). The interposers may include portions diced from a wafer or comprise a silicon wafer itself. The area of the interposer may be broader by an area required in implementing a fan out of the semiconductor chip than that of the semiconductor chip. The stack package may further include a seed metal layer patterned from the bonding pad to the interconnection terminal groove. The redistribution pattern and the interconnection terminal may be plated on the seed metal layer. The stack package may further include a passivation layer formed between the semiconductor chip and the seed metal layer. The stack package may further include an external connection terminal connecting the exposed interconnection terminals to one another when the plurality of interposers are stacked with one another. The stack package may further include a module substrate having a substrate pad on which one or more interposers are stacked. The interconnection terminals may be connected to the substrate pad. The stack package may further include an aligner for aligning the position of the semiconductor chip when inserting the semiconductor chip into the cavity.

According to an aspect of the present invention, there is provided a stack package which includes at least one or more interposers in which a semiconductor chip having a bonding pad are inserted, an interconnection terminal groove is formed due to a difference of the areas between the semiconductor chip and a cavity into which the semiconductor chip is inserted, and an interconnection terminal connected to the bonding pad is formed in the interconnection terminal groove, wherein the interposers are stacked with one another and the interconnection terminals are connected to one another such that at least one or more semiconductor chips are stacked and electrically connected.

The interconnection terminal may be exposed by polishing the rear surface of the interposer until the interconnection terminal groove is exposed. The stack package may further include an elastomer filled in a portion of the interconnection terminal groove. The interposer may be one of a silicon wafer, a glass substrate, and a printed circuit board (PCB). The interposers may comprise a portion of a diced wafer or comprise a silicon wafer itself. The area of the interposer may be broader by an area required in implementing a fan out of the semiconductor chip than that of the semiconductor chip. The stack package may further include an aligner for aligning the position of the semiconductor chip when inserting the semiconductor chip into the cavity.

According to an aspect of the present invention, there is provided a method of manufacturing a stack package, which includes: inserting a semiconductor chip into an interposer having a cavity; forming an interconnection terminal in an interconnection terminal groove formed due to a difference of the areas between the cavity and the semiconductor chip, and connecting the interconnection terminal to a bonding pad formed on the semiconductor chip; polishing the rear surface of the interposer such that the interconnection terminal is exposed; and stacking one or more interposers, and connecting the interconnection terminals to one another.

Here, the method for packaging a stack package may further include filling an elastomer in a portion of the interconnection terminal groove. The interposers may comprise a portion of a diced wafer or comprise a silicon wafer itself.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A stack package comprising:
a plurality of semiconductor chips each having a bonding pad;
a plurality of interposers each having a cavity in which the semiconductor chip is disposed and an interconnection terminal groove between the semiconductor chip and a sidewall of the cavity; and
a redistribution pattern connecting the bonding pad to interconnection terminals disposed in the interconnection terminal groove,
wherein the interconnection terminals are exposed by a rear surface of the interposer.

2. The stack package of claim 1, wherein the plurality of interposers are stacked with one another and the exposed interconnection terminals are connected to one another such that the plurality of semiconductor chips are stacked and electrically connected with one another.

3. The stack package of claim 1, further comprising an elastomer filled in a portion of the interconnection terminal grooves.

4. The stack package of claim 1, wherein the interposers comprise one of a silicon wafer, a glass substrate, and a printed circuit board (PCB).

5. The stack package of claim 1, wherein the interposers comprise portions diced from a wafer or comprise a silicon wafer itself.

6. The stack package of claim 1, wherein the area of each of the interposers is broader by an area required in implementing a fan out of the semiconductor chip than that of the semiconductor chip.

7. The stack package of claim 1, further comprising a seed metal layer disposed from the bonding pad to the interconnection terminal groove,
wherein the redistribution pattern and the interconnection terminal are plated on the seed metal layer.

8. The stack package of claim 7, further comprising a passivation layer disposed between the semiconductor chip and the seed metal layer.

9. The stack package of claim 1, further comprising an external connection terminal electrically connecting the exposed interconnection terminals to one another.

10. The stack package of claim 1, further comprising a module substrate having a substrate pad on which one or more interposers are stacked,
wherein the interconnection terminals are connected to the substrate pad.

11. The stack package of claim 1, further comprising an aligner for aligning a position of the semiconductor chip when inserting the semiconductor chip into the cavity.

1. A stack package comprising:
one or more interposers, each of the interposers including:
a cavity in which a semiconductor chip having a bonding pad is disposed;
an interconnection terminal groove disposed between the semiconductor chip and a sidewall of the cavity; and
an interconnection terminal disposed in the interconnection terminal groove and connected to the bonding pad,
wherein the interposers are stacked with one another and the interconnection terminals are connected to one another such that the semiconductor chips are stacked and electrically connected.

13. The stack package of claim 12, wherein the interconnection terminal is exposed by a rear surface of the interposer.

14. The stack package of claim 12, further comprising an elastomer disposed in a portion of the interconnection terminal groove.

15. The stack package of claim 12, wherein the interposer is one of a silicon wafer, a glass substrate, and a printed circuit board (PCB).

16. The stack package of claim 12, wherein the interposers comprise a portion of a diced wafer or comprise a silicon wafer itself.

17. The stack package of claim 12, wherein an area of the interposer is broader by an area required in implementing a fan out of the semiconductor chip than that of the semiconductor chip.

18. The stack package of claim 12, further comprising an aligner for aligning a position of the semiconductor chip when inserting the semiconductor chip into the cavity.
